(19) United States
(12) Patent Application Publication
(10) Pub. No.: US 2003/0109138 A1
(43) Pub. Date: Jun. 12, 2003

(54) Method of etching tantalum

(75) Inventor: Padmapani Nallan, San Jose, CA (US)

Correspondence Address: Patent Counsel, Applied Materials, Inc., P.O. Box 450 A, Santa Clara, CA, 95052, US

(73) Assignee: Applied Materials, Inc., Santa Clara, CA (US)

(21) Appl. No.: 10/340,125

(22) Filed: Jan. 9, 2003

Related U.S. Application Data
(63) Continuation of application No. 09/759,725, filed on Jan. 12, 2001.

(51) Int. Cl. H01L 21/302; H01L 21/461

(52) U.S. Cl. 438/689

(57) ABSTRACT

A method of plasma etching a patterned tantalum layer or a patterned tantalum nitride layer in a semiconductor structure is disclosed. The method provides an advantageous etch rate while enabling excellent profile control during the patterned etching of the tantalum. The method of etching tantalum employs a plasma source gas comprising an inorganic fluorine-comprising gas, such as NF₃ or SF₆, in combination with a carbon-containing, fluorine-comprising gas, CₓH_{y}F_{z}, where x ranges from 1 to about 4, y ranges from 0 to about 4, and z ranges from 1 to about 6. In some of the preferred embodiments, y=0 in the CₓH_{y}F_{z} formula, so that the carbon-containing, fluorine-comprising gas has the formula CₓF_{y}. Examples of such carbon-containing, fluorine-comprising gases include CF₄, C₂F₆, C₃F₆, C₄F₆, C₄F₈, C₅F₈, and combinations thereof. The inorganic fluorine-comprising gas serves as the primary etchant, in order to provide a high tantalum etch rate (i.e., greater than 1000 Å per minute). The carbon-containing, fluorine-comprising gas serves as a secondary etchant, as well as providing sidewall passivation to improve the feature etch profile. By changing the ratio of the inorganic fluorine-comprising gas to the organic fluorine-comprising gas in the plasma source gas, the etch rate and etch profile of the tantalum can be accurately controlled. To achieve best results using the method of the invention, the plasma is preferably a high density plasma having an electron density of at least at least 10¹¹ e⁻cm³. In addition, a bias power is applied to the semiconductor substrate to increase the anisotropicity of the etching process.

### BACKGROUND OF THE INVENTION

1. Field of the Invention

The present invention pertains to a method of etching a layer of tantalum within a semiconductor structure. The method of the invention is particularly useful in etching patterned structures such as a tantalum gate, but may also be used for surface etch back of a tantalum layer.

2. Brief Description of the Background Art

The use of metal gates within semiconductor structures is a relatively new concept in the art of semiconductor manufacture. Tantalum is one material that is under investigation for use in gates.

Tantalum and tantalum nitride have been frequently used in the past as barrier layer materials in copper metallization structures, to prevent the migration of silicon from an underlying substrate into an overlying copper metallization layer. However, among the refractory metals, molybdenum and tungsten have been most widely recommended as MOS gates on grounds that the gate material must be stable with respect to the gate dielectric, which is typically SiO₂ or Si₃N₄. The use of metals such as titanium and tantalum has been rejected because such materials have been considered to be too reactive with oxides and nitrides at semiconductor processing temperatures (for example, at temperatures of approximately 600° C., or greater).

The etching of molybdenum has been carrier out using CF₄, with a small amount of oxygen added to increase the etch rate. In the alternative, NF₃ or SF₆ has been used, rather than the CF₄/O₂ combination, to provide for the more rapid generation of fluorine atoms or radicals. The dilution of NF₃ or SF₆ with O₂ or a conventional diluent, such as Ar or He, has been recommended against, as this is said to lead only to a reduced metal etch rate.

Conventional chemistry for etching tantalum layers used in interconnect applications has involved the use of CF₄ or CF₄/O₂. However, the tantalum etch profiles obtained using these gases as a plasma source gas are not ideal.

Additional information pertaining to the etching of tantalum layers in general may be found in U.S. Pat. No. 4,411,734, to Maa; U.S. Pat. No. 4,849,376, to Balzan et al.; and Chow et al., “Plasma etching of refractory gates for VLSI applications”, J. Electrochem. Soc., Vol. 131, No. 10, pp. 2325-2335 (1984), for example.

If tantalum is used as a gate material in combination with an underlying dielectric material which provides a stable overall structure, then it is necessary to provide a method of plasma etching the tantalum gate material at a desirable etch rate, in a manner which provides adequate control over etch profile, and with adequate selectivity for etching the tantalum in preference over the underlying dielectric material.

### SUMMARY OF THE INVENTION

We have discovered a method of plasma etching a patterned tantalum layer in a semiconductor structure. The method provides an advantageous etch rate while enabling excellent profile control during the patterned etching of the tantalum. The method of etching tantalum employs a plasma source gas comprising an inorganic fluorine-comprising gas, such as NF₃ or SF_{6, i}n combination with a carbon-containing, fluorine-comprising gas, CₓH_{y}F_{z}, where x ranges from 1 to about 4, y ranges from 0 to about 4 and z ranges from 1 to about 6. In some of the preferred embodiments, y=0 in the CₓH_{y}F_{z} formula, so that the carbon-containing, fluorine-comprising gas has the formula CₓF_{y}. Examples of such carbon-containing, fluorine-comprising gases include CF₄, C₂F₆, C₃F₆, C₄F₆, C₄F₈, C₅F₈, and combinations thereof.

The inorganic fluorine-comprising gas serves as the primary etchant, in order to provide a high tantalum etch rate (i.e., greater than 1000 Å per minute). The carbon-containing, fluorine-comprising gas serves as a secondary etchant, as well as providing sidewall passivation to improve the feature etch profile.

The plasma source gas may optionally include a non-reactive, diluent gas, such as, for example, argon, helium, xenon, neon, krypton, or combinations thereof. The concentration of the non-reactive, diluent gas is typically less than 50% by volume of the plasma source gas.

By changing the ratio of the inorganic fluorine-comprising gas to the organic fluorine-comprising gas in the plasma source gas, the etch rate and etch profile of the tantalum can be accurately controlled. We have discovered that providing the inorganic fluorine-comprising gas and the organic fluorine-comprising gas in a volumetric ratio within the range of about 3:1 to about 1:3 provides excellent results, in terms of both etch rate and etch profile. Typically, the source gas comprises NF₃ and CₓF_{y} (where x ranges from about 1 to about 4, and y ranges from about 1 to about 6), and the NF₃ and the CₓF_{y} gases are provided at a volumetric ratio of NF₃:CₓF_{y} within the range of about 5:1 to about 1:5. In one embodiment where the plasma source gas comprises NF₃ and CF₄, the volumetric ratio of NF₃: CF₄ ranges from about 2.5:1 to about 1:2.5. Excellent results were obtained at an NF₃: CF₄ ratio of 1:1.

If the organic fluorine-comprising gas also contains hydrogen (i.e., has the chemical formula CₓH_{y}F_{z}, for example, CHF₃ or CH₂F₂), the amount of sidewall passivation will be increased. In this case, the relative amount of the inorganic fluorine-comprising gas to the CₓH_{y}F_{z} gas should be increased in order to provide the optimum balance between etch rate and sidewall passivation.

To achieve best results using the method of the invention, the plasma is preferably a high density plasma having an electron density of at least at least 10¹¹ e⁻/cm³. In addition, a bias power is applied to the semiconductor substrate to provide more anisotropic etch conditions. Typically, the substrate bias power applied when using a CENTURA® DPS™ silicon etch chamber, or similar processing apparatus, ranges from about 30 W to about 300 W. This combination of process variables, in addition to others which will be specified later, provides vertical (about 88° to 90°) profile sidewalls for etched tantalum lines.

The invention provides a method for etching a layer of tantalum within a semiconductor structure which allows excellent control over the tantalum etch rate and the feature etch profile.

### BRIEF DESCRIPTION OF THE DRAWINGS

FIG. 1 shows an example of an apparatus which can be used to carry out the etching processes described herein.

FIG. 2A shows a beginning semiconductor structure 200 for performing the method of the invention. The semiconductor structure 200 includes, from top to bottom, a patterned layer 210 of photoresist, a dielectric ARC (DARC) layer 208, a tantalum gate layer 206, and a layer 204 of silicon oxide, all deposited on a silicon substrate 202. The relative thicknesses of the film stack layers are not shown to scale.

FIG. 2B shows the semiconductor structure 200 after etching of the DARC layer 208.

FIG. 2C shows the semiconductor structure 200 after etching the tantalum gate layer 206, exposing the underlying silicon oxide layer 204.

### DETAILED DESCRIPTION OF THE PREFERRED EMBODIMENTS

Described in detail below is a method of etching a layer of tantalum within a semiconductor structure. In particular, the method comprises exposing the layer of tantalum to a plasma generated from a source gas comprising a combination of an inorganic fluorine-comprising gas and an organic fluorine-comprising gas. Preferred processing conditions for performing the method of the invention are set forth below.

As a preface to the detailed description, it should be noted that, as used in this specification and the appended claims, the singular forms “a”, “an”, and “the” include plural referents, unless the context clearly dictates otherwise.

### I. An Apparatus for Practicing the Invention

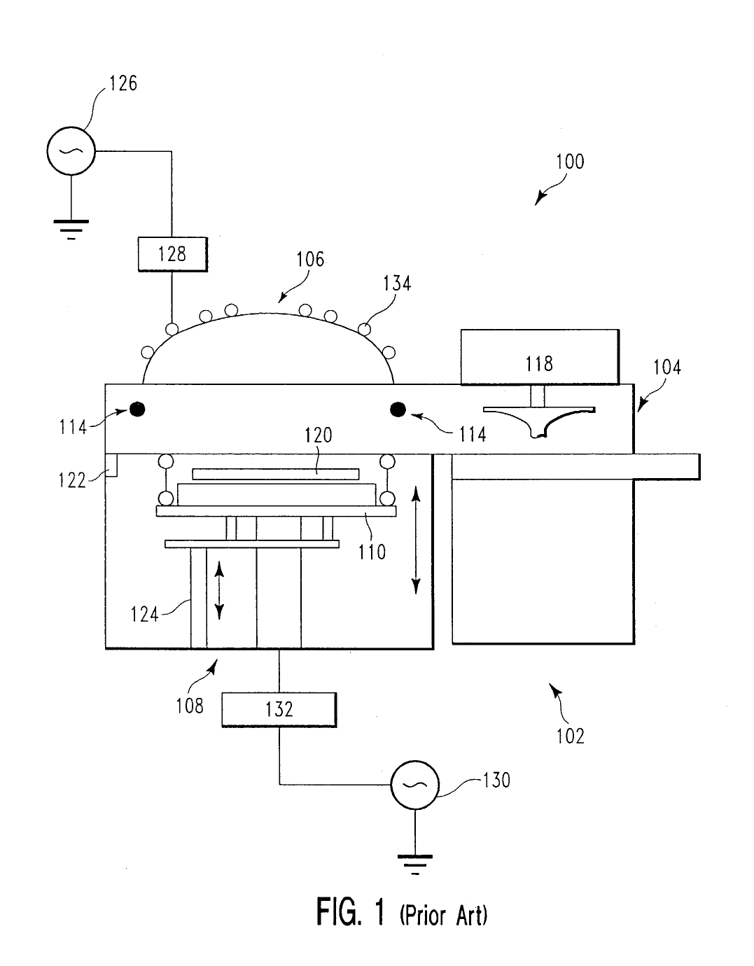

The embodiment etch processes described herein were carried out in a CENTURA® Integrated Processing System, available from Applied Materials, Inc., of Santa Clara, Calif. The system is shown and described in U.S. Pat. No. 5,186,718, the disclosure of which is hereby incorporated by reference. Although the etch process chamber used in the Examples presented herein is shown in schematic in FIG. 1, any of the etch processors available in the industry should be able to take advantage of the etch chemistry described herein, with some adjustment to other process parameters. The equipment shown in schematic in FIG. 1 includes a Decoupled Plasma Source (DPS) of the kind described by Yan Ye et al. at the Proceedings of the Eleventh International Symposium of Plasma Processing (May 7, 1996) and published in the Electrochemical Society Proceedings (Volume 96-12, pp. 222-233, 1996), which is hereby incorporated by reference. The plasma processing chamber enables the processing of an 8 inch (200 mm) diameter wafer.

FIG. 1 shows a schematic of a side view of an individual CENTURA® DPS™ polysilicon etch chamber 100. The etch chamber 100 consists of an upper chamber 104 having a ceramic dome 106, and a lower chamber 108. The lower chamber 108 includes a monopolar electrostatic chuck (ESC) cathode 110. Gas is introduced into the chamber via gas injection nozzles 114 for uniform gas distribution. Chamber pressure is controlled by a closed-loop pressure control system (not shown) using a throttle valve 118. During processing, a substrate 120 is introduced into the lower chamber 108 through inlet 122. The substrate 120 is held in place by means of a static charge generated on the surface of electrostatic chuck (ESC) cathode 110 by applying a DC voltage to a conductive layer (not shown) located under a dielectric film (not shown) on the chuck surface. The cathode 110 and substrate 120 are then raised by means of a wafer lift 124 and sealed against the upper chamber 104 in position for processing. Etch gases are introduced into the upper chamber 104 via gas injection nozzles 114. The etch chamber 100 uses an inductively coupled plasma source power 126 and matching network 128 operating at 12.56 MHZ for generating and sustaining a high density plasma. The wafer is biased with an RF source 130 and matching network 132 operating at 13.56 MHZ. Plasma source power 126 and substrate biasing means 130 are controlled by separate controllers (not shown).

Although the Examples provided herein were carried out using an inductively coupled etch system, a capacitive etch tool, such as an eMaX™ CENTURA® etch system (not shown), available from Applied Materials, Inc., can also be used in the etch processes described herein.

### II. Method of Etching Tantalum

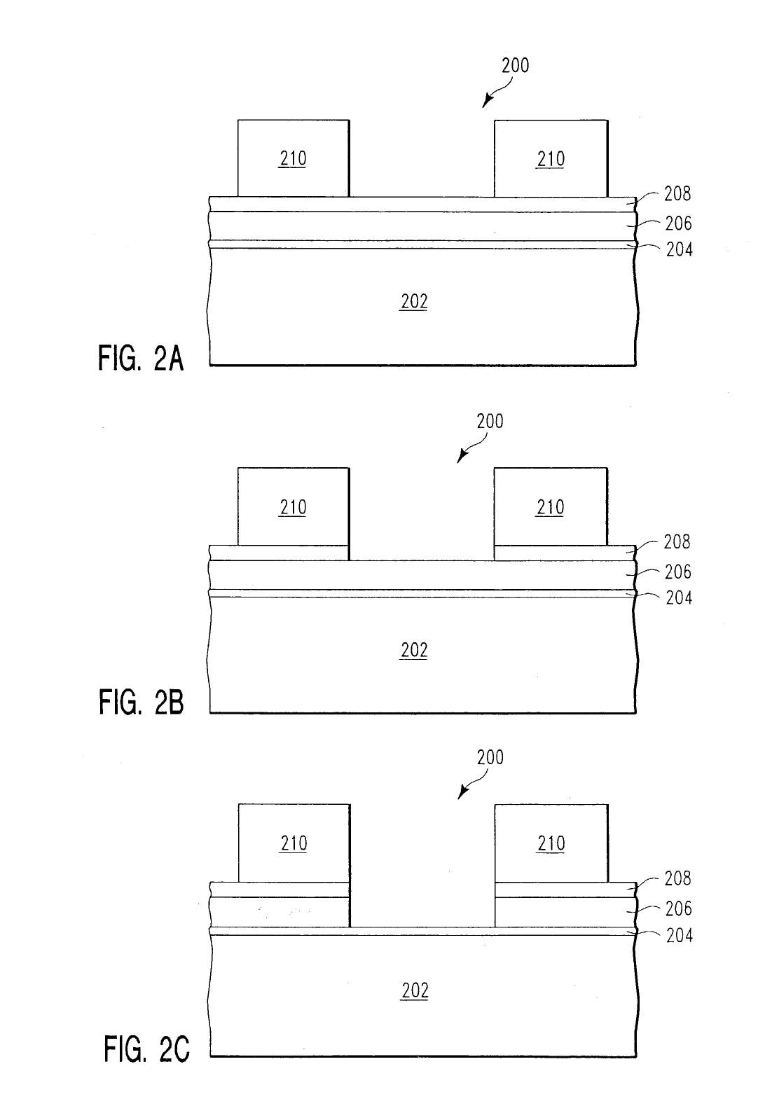

Referring to the figures, FIG. 2A shows a beginning semiconductor structure 200 of the kind which is illustrative of the method of the invention. FIG. 2A is not to scale. The semiconductor structure 200 includes, from top to bottom, a patterned layer 210 of photoresist, a dielectric ARC (DARC) layer 208, a tantalum gate layer 206, and a layer 204 of an oxide (or silicon nitride), all deposited on a substrate 202, which is typically silicon. The term “ARC” refers to a layer of material that is used as an anti-reflective coating.

The thickness and patterning method for the photoresist layer 210 will depend on the particular photoresist material used. Photoresist layer 210 may be any suitable photoresist material known in the art. Typically, the photoresist is an organic, carbon-containing material. A frequently used photoresist is a DUV (Deep U.V.) photoresist available from either JSR® or SHIPLEY®, INC. A typical film thickness for such a DUV photoresist ranges from about 4000 Å to about 10,000 Å.

The DARC layer 208 typically comprises silicon oxynitride (SiOₓN_{y}) and is commonly formed to have a thickness within the range of about 300 Å to about 600 Å. The silicon oxynitride DARC layer 208 is generally deposited using conventional methods known in the art, such as plasma-enhanced chemical vapor deposition (PECVD). The use of an organic-based ARC layer is also contemplated as a part of this disclosure.

The tantalum layer 206, from which the gate is to be formed, typically exhibits a thickness within the range of about 500 Å to about 2000 Å. The gate layer 206 may alternatively comprise tantalum nitride. The tantalum or tantalum nitride gate layer 206 is typically deposited using conventional methods known in the art, such as chemical vapor deposition (CVD) or physical vapor deposition (PVD).

When oxide layer 204 is silicon oxide, for example, the oxide layer 204 thickness commonly ranges from about 15 Å to about 50 Å. When the oxide layer is tantalum pentoxide (Ta₂O₅), for example, the oxide layer thickness commonly ranges from about 30 Å to about 200 Å. Such oxide layers are typically deposited using conventional methods known in the art, such as thermal oxidation or plasma-enhanced chemical vapor deposition (PECVD).

After patterning of the photoresist layer 210 to achieve the structure shown in FIG. 2A, the DARC layer 208 is etched, as shown in FIG. 2B, to expose a surface of the tantalum gate layer 206. The DARC layer 208 can be etched using conventional etch chemistry and methodology known in the art, depending on the particular material which comprises the DARC layer. If the DARC layer comprises silicon oxynitride, the silicon oxynitride is typically etched using the following process conditions: 80 sccm CF₄; 500 W plasma source power; 120 W substrate bias power; 4 mTorr process chamber pressure; and a substrate temperature of 50° C. substrate temperature. Etch time typically ranges from about 10 to about 30 seconds, depending on the thickness of the DARC layer.

After etching of the DARC layer 208, the tantalum gate layer 206 is etched, according to the method of the invention, using a plasma generated from a source gas comprising a combination of an inorganic fluorine-comprising gas and an organic fluorine-comprising gas. The inorganic fluorine-comprising gas is typically selected from the group consisting of NF₃ and SF₆. The organic fluorine-comprising gas typically has the formula CₓH_{y}F_{z}, where x ranges from about 1 to about 4, where y ranges from 0 to about 4, and where z ranges from 1 to about 6. When y=0, the CₓH_{y}F_{z} gas is typically selected from the group consisting of CF₄, C₂F₆, C₃F₆, C₄F₆, C₄F₈, C₅F₈, and combinations thereof. When y≠0, the CₓH_{y}F_{z} gas is typically selected from the group consisting of CHF₃ and CH₂F₂.

The plasma source gas may optionally include a non-reactive, diluent gas, such as, for example, argon, helium, xenon, neon, krypton, or combinations thereof. The concentration of the non-reactive, diluent gas is typically less than 50% by volume of the plasma source gas.

By changing the ratio of the inorganic fluorine-comprising gas to the organic fluorine-comprising gas in the plasma source gas, the etch rate and etch profile of the tantalum layer can be accurately controlled. We have found that providing the inorganic fluorine-comprising gas and the organic fluorine-comprising gas in a volumetric ratio within the range of about 5:1 to about 1:5, and preferably in the range of about 3:1 to about 1:3, provides excellent results, in terms of both etch rate and etch profile. In one of applicants' more preferred embodiments, the source gas for etching a tantalum gate comprises NF₃ and CₓF_{y}, and the NF₃ and the CₓF_{y} gas are provided at a volumetric ratio of NF₃:CₓF_{y} within the range of about 2.5:1 to about 1:2.5.

The entire thickness of the tantalum gate layer 206 is etched, exposing the underlying silicon oxide layer 204. An emission endpoint detection system may be used to detect breakthrough to the underlying silicon oxide layer 204. A timed endpoint may be used when the etch selectivity of the tantalum layer 206 relative to silicon oxide layer 204 is at least 50:1, so that tantalum can be etched rapidly without etching through the underlying silicon oxide layer.

Typical process conditions for etching tantalum according to the method of the invention are presented in Table One, below.

TABLE ONE
Typical Process Conditions for Etching Tantalum in a
CENTURA ® DPS ™ TM Polysilicon Etch Chamber

| | Typical | | Optimum |
|---|---|---|---|
| | Process | Preferred Process | Known Process |
| Process Parameter | Conditions | Conditions | Conditions |
| Total Plasma Source Gas Flow Rate | 50-200 | 50-150 | 80-120 |
| (sccm) | | | |
| NF₃ Flow Rate (sccm) | 30-100 | 30-70 | 30-50 |
| CF₄ Flow Rate (sccm) | 30-100 | 30-70 | 50-70 |
| Plasma Source Power* (W) | 300-2000 | 600-1000 | 600-800 |
| Substrate Bias Power** (W) | 30-300 | 40-200 | 80-150 |
| Process Chamber Pressure (mTorr) | 2-50 | 2-20 | 4-6 |
| Substrate Temperature (° C.) | 10-100 | 30-70 | 40-60 |
| *The term “bias power” refers to the power applied to the substrate (typically, to the substrate support pedestal) to produce a negative voltage on the substrate surface. | | | |
| # Generally, the negative voltage is used to attract high energy species to the substrate surface. The higher the negative voltage, the greater the attraction. | | | |

**The term “source power” refers to the power that is applied to generate and sustain the plasma within the processing chamber.

We performed various experimental runs during development of the tantalum etch method of the invention. These experiments were performed using the following film stack (layers listed from top to bottom): a 5500 Å Shipley DUV photoresist layer (previously patterned); a 300 Å SiOₓN_{y} DARC layer; a 2500 Å Ta layer; and a 35 Å SiO₂ layer, all deposited on a silicon substrate.

Eight experimental runs are described below. In each experimental run, after patterning of the photoresist layer, a DARC etch step was performed to expose a surface of the tantalum gate layer (as shown in FIG. 2B). For Run #1, the DARC etch step was performed using the following process conditions: 100 sccm CF₄; 300 W plasma source power; 60 W bias power; 4 mTorr process chamber pressure; 50° C. substrate temperature; and 50 seconds+30% etch time. For Run #2, the DARC etch step was performed using the following process conditions: 80 sccm CF₄; 500 W plasma source power; 120 W bias power; 4 mTorr process chamber pressure; 50° C. substrate temperature; and 19.7 seconds+30% etch time. For Runs #3-8, the DARC etch step was performed using the following process conditions: 80 sccm CF₄; 500 W plasma source power; 120 W bias power; 4 mTorr process chamber pressure; 50° C. substrate temperature; and 15 seconds+30% etch time.

### COMPARATIVE EXAMPLES

The underlying tantalum gate layer was then etched (as shown in FIG. 2C). Etching of the tantalum layer in Runs #1, 2, and 3 was performed using single plasma source gases. CF₄ only was used in Runs #1 and 2. For Run #1, the tantalum etch step was performed using the following process conditions: 100 sccm CF₄; 300 W plasma source power; 60 W bias power; 4 mTorr process chamber pressure; 50° C. substrate temperature; and 110 seconds etch time. The use of CF₄ as the sole etchant gas in Run #1 resulted in a slightly tapered etch profile and low selectivity for etching the tantalum gate layer relative to the photoresist layer.

The term “etch profile” (or “feature profile”), as used above, generally refers to, but is not limited to, a cross-sectional view of a gate structure, as shown in FIGS. 2A through 2C, and is described in terms of an angle between the etched sidewall of a gate layer and a horizontal line at the upper surface of the underlying layer of silicon oxide. The term “vertical profile” refers to a cross-sectional view of the etched gate layer, where the sidewalls of the etched gate layer are essentially perpendicular to the silicon oxide surface. The term “undercut” profile refers to a cross-sectional view of the etched gate layer, where the width of the etched opening is larger as the distance away from the opening on the substrate increases. The term “tapered” profile refers to a cross-sectional view of the etched gate layer, where the width of the etched opening is smaller as the distance away from the opening on the substrate surface increases. The term “critical dimension” typically refers to the smallest dimension of the feature which must be controlled to produce the desired structure.

Run #2 utilized the same plasma source gas and flow rate as Run #1, with the plasma source power increased to 600 W, and the bias power increased to 120 W. All other etch process conditions were the same as those used in Run #1. The use of CF₄ as the sole etchant gas in Run #2 resulted in a tapered etch profile and low selectivity for etching the tantalum gate layer relative to the photoresist layer. Increasing the plasma source power and the bias power in Run #2 (as compared to Run #1) resulted in low selectivity for etching the tantalum gate layer relative to the silicon oxynitride DARC layer.

Wafers etched in Run #2 exhibited center fast non-uniformity. As used herein, the term “center fast non-uniformity” refers to a tantalum etch rate which is greater at the center of the wafer than at the edge of the wafer. By contrast, “edge fast non-uniformity” refers to a tantalum etch rate which is greater at the edge of the wafer than at the center of the wafer.

Run #3 utilized the same etch process conditions as Run #2, with the exception that NF₃ (rather than CF₄) was used as the plasma source gas. Etch time for Run #3 was 70 seconds. The use of NF₃ as the sole etchant gas in Run #3 provided a high tantalum etch rate, but a severely undercut etch profile. Wafers etched in Run #3 exhibited edge fast non-uniformity.

### METHOD OF THE INVENTION EXAMPLES

In experimental runs #4-8, we used a new approach, where a combination of an inorganic, fluorine-comprising gas and a carbon-containing, fluorine-comprising gas were included in the plasma source gas. In particular, plasma source gas compositions comprising various combinations of CF₄ and NF₃ were evaluated. Runs #4-7 utilized a plasma source gas composition comprising 70 sccm CF₄ in combination with 30 sccm NF₃.

Tantalum etch process conditions for Run #4 were as follows: 600 W plasma source power; 120 W bias power; 4 mTorr process chamber pressure; 50° C. substrate temperature; and 60 seconds etch time. These process conditions provided a vertical etch profile, with no etch rate or profile microloading. Wafers etched in Run #4 exhibited edge fast non-uniformity.

In Run #5, the bias power was increased to 150 W, with all other variables held constant with reference to Run #4. The use of a higher bias power resulted in a slightly more tapered etch profile and much better etch uniformity across the wafer, as compared to Run #4.

In Run #6, the source power was increased to 800 W, with all other variables held constant with reference to Run #4. The use of a higher plasma source power resulted in a more tapered etch profile and a higher tantalum etch rate, as compared to Run #4. Wafers etched in Run #6 exhibited edge fast non-uniformity.

In Run #7, the process chamber pressure was increased to 8 mTorr, with all other variables held constant with reference to Run #4. The use of a higher process chamber pressure resulted in a more tapered etch profile and a higher tantalum etch rate, as compared to Run #4. Wafers etched in Run #7 exhibited edge fast non-uniformity.

Run #8 utilized a plasma source gas composition comprising 50 sccm CF₄ in combination with 50 sccm NF₃. The tantalum etch process conditions were the same as those used in Run #4. Increasing the relative amount of NF₃ in the plasma source gas provided a more vertical etch profile and a higher tantalum etch rate, as compared to Run #4. Edge fast non-uniformity was observed.

When all other process conditions are held constant (at about 100 sccm of total gas flow, 4 mTorr process chamber pressure, 600 W source power, 120 W bias power, and a substrate temperature of 50° C.), the use of a plasma source gas composition having a volumetric ratio of NF₃: CF₄ of approximately 0.4:1 (Run #4, above) provides a tantalum etch rate of approximately 1650 Å per minute, and an etch profile angle of approximately 88°. The use of a plasma source gas composition having a volumetric ratio of NF₃:CF₄ of approximately 1:1 (Run #8, above) provides a tantalum etch rate of approximately 2000 Å per minute, and an etch profile angle of approximately 90°. As demonstrated above, by changing the ratio of the inorganic fluorine-comprising gas to the organic fluorine-comprising gas in the plasma source gas, it is possible to accurately control the etch rate and etch profile of the tantalum gate layer.

As demonstrated above, the method of the invention for etching a tantalum layer within a semiconductor structure provides excellent control over the tantalum etch rate, feature etch profile, and feature critical dimensions.

Our best results were obtained using a plasma source gas comprising NF₃ and CF₄ in a volumetric ratio of approximately 1:1. However, the volumetric ratio of NF₃ to CF₄ used in a particular tantalum gate etch process will depend upon a number of factors which pertain to the particular stack of materials being etched, such as the thickness of the tantalum gate, for example. In addition, adjustments will need to be made in view of the apparatus used to carry out the method.

If the organic fluorine-comprising gas also contains hydrogen (i.e., has the chemical formula CₓH_{y}F_{z}), the amount of sidewall passivation will be increased. In this case, the amount of the inorganic fluorine-comprising gas relative to the CₓH_{y}F_{z} gas should be increased in order to provide the optimum balance between etch rate and sidewall passivation.

The examples described above utilized an organic photoresist material for patterning of the tantalum layer. As the organic photoresist is partially consumed during etching of the tantalum layer, free carbon is released, which contributes to the amount of sidewall passivation. Alternatively, a patterned hard masking material (such as silicon nitride) can be used in lieu of a photoresist. If a hard mask is used (with no overlying photoresist), the amount of the CₓH_{y}F_{z} gas relative to the inorganic fluorine-comprising gas should be increased in order to provide the optimum balance between etch rate and sidewall passivation.

The above described preferred embodiments are not intended to limit the scope of the present invention, as one skilled in the art can, in view of the present disclosure expand such embodiments to correspond with the subject matter of the invention claimed below.

We claim:

1. A method of etching a patterned tantalum layer within a semiconductor structure, comprising exposing a layer of tantalum to a plasma generated from a source gas comprising a combination of an inorganic fluorine-comprising gas and an organic fluorine-comprising gas.

2. The method of claim 1, wherein said inorganic fluorine-comprising gas is selected from the group consisting of NF₃ and SF₆.

3. The method of claim 1, wherein said organic fluorine-comprising gas has the formula CₓH_{y}F_{z}, and wherein x ranges from about 1 to about 4, y ranges from 0 to about 4, and z ranges from about 1 to about 6.

4. The method of claim 3, wherein y=0, and said CₓH_{y}F_{z} gas is selected from the group consisting of CF₄, C₂F₆, C₃F₆, C₄F₆, C₄F₈, C₅F₈, and combinations thereof.

5. The method of claim 4, wherein said CₓH_{y}F_{z} gas is CF₄.

6. The method of claim 3, wherein y≠0, and said CₓH_{y}F_{z} gas is selected from the group consisting of CHF₃, CH₂F₂, and combinations thereof.

7. The method of claim 1, wherein said inorganic fluorine-comprising gas and said organic fluorine-comprising gas are present in said source gas at a volumetric ratio within the range of about 5:1 to about 1:5.

8. The method of claim 6, wherein said inorganic fluorine-comprising gas and said organic fluorine-comprising gas are present in said source gas at a volumetric ratio within the range of about 3:1 to about 1:3.

9. The method of claim 7, wherein said inorganic fluorine-comprising gas is NF₃ and said organic fluorine-comprising gas is CF₄, and wherein said NF₃ and said CF₄ are present in said source gas at a volumetric ratio within the range of about 2.5:1 to about 1:2.5 NF₃:CF₄.

10. The method of claim 8, wherein said inorganic fluorine-comprising gas is NF₃ and said organic fluorine-comprising gas is CF₄, and wherein said NF₃ and said CF₄ are present in said source gas at a volumetric ratio of approximately 1:1 NF₃:CF₄.

11. The method of claim 1, wherein said source gas further comprises a non-reactive, diluent gas selected from the group consisting of argon, helium, xenon, neon, and krypton.

12. The method of claim 10, wherein said non-reactive, diluent gas is present in said source gas at a concentration of 50% or less by volume of said source gas.

13. The method of claim 1, wherein said plasma is a high density plasma having an electron density of at least at least 10¹¹ e⁻/cm³.
